(19) United States
(12) Patent Application Publication
(10) Pub. No.: US 2009/0305515 A1
(43) Pub. Date: Dec. 10, 2009

(54) METHOD AND APPARATUS FOR UV CURING WITH WATER VAPOR

(76) Inventors: Dustin Ho, (US); Scott Hendrickson, Brentwood, CA (US); Juan Carlos Rocha-Alvarez, San Carlos, CA (US); Sanjeev Baluja, Sunnyvale, CA (US); Thomas Nowak, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/134,413

(22) Filed: Jun. 6, 2008

(51) Int. Cl. H01L 21/31; H01L 21/00; C23C 16/00

(52) U.S. Cl. 438/778; 438/795; 118/722; 257/E21.24; 257/E21.001

(57) ABSTRACT

Embodiments of the invention generally relate to a method and apparatus for curing dielectric material deposited in trenches or gaps in the surface of a substrate to produce a feature free of voids and seams. In one embodiment, the dielectric material is steam annealed while being exposed to ultraviolet radiation. In one embodiment, the dielectric material is further thermally annealed in a nitrogen environment.

### BACKGROUND OF THE INVENTION

1. Field of the Invention

Embodiments of the present invention generally relate to a method and apparatus for curing dielectric material to produce isolation structures and the like that are free of voids and seams.

2. Description of the Related Art

Modern integrated circuits are complex devices that may include millions of components on a single chip; however, the demand for faster, smaller electronic devices is ever increasing. This demand not only requires faster circuits, but it also requires greater circuit density on each chip. In order to achieve greater circuit density, not only must device feature size be reduced, but isolation structures between devices must be reduced as well.

Current isolation techniques include shallow trench isolation (STI) processes. STI processes include first etching a trench having a predetermined width and depth into a substrate. The trench is then filled with a layer of dielectric material. The dielectric material is then planarized by, for example, chemical-mechanical polishing (CMP).

As the width of trenches continues to shrink, the aspect ratio (depth divided by width) continues to grow. One challenge regarding the manufacture of high aspect ratio trenches is avoiding the formation of voids during the deposition of dielectric material in the trenches.

To fill a trench, a layer of dielectric material, such as silicon oxide, is first deposited. The dielectric layer typically covers the field, as well as the walls and the bottom of the trench. If the trench is wide and shallow, it is relatively easy to completely fill the trench. However, as the aspect ratio increases, it becomes more likely that the opening of the trench will “pinch off”, trapping a void within the trench.

To decrease the likelihood of trapping a void within the trench, high aspect ratio processes (HARP) may be used to form the dielectric material. These processes include depositing the dielectric material at different rates in different stages of the process. A lower deposition rate may be used to form a more conformal dielectric layer in the trench, and a higher deposition rate may be used to form a bulk dielectric layer above the trench.

Another challenge in filling high aspect ratio trenches is avoiding the formation of weak seams at the interface of the dielectric material with itself. Weak seams can form when the deposited dielectric material either weakly adheres or fails to adhere to itself as it grows inwardly from the opposite walls of the trench.

The dielectric material along a seam has a lower density and higher porosity than other portions of the dielectric material, which may cause an enhanced rate of dishing when the dielectric material is exposed to an etchant during subsequent processes such as CMP. Like voids, weak seams create inhomogeneities in the dielectric strength of the gap fill that can adversely affect the operation of a semiconductor device.

Voids and seams in the dielectric material may be repaired by steam annealing the substrate in a high temperature furnace. Following the steam anneal, the substrate may additionally be placed in a high temperature nitrogen environment to densify the dielectric material. Furnace annealing functions well to repair the voids or seams in the dielectric material. However, certain limitations of furnace annealing exist due to the size of the furnace and its impact on processing the substrates.

The typical furnace is sized to process substrates in large batches, which may lead to limited of control, uniformity, and throughput. Control and flexibility of the reaction environment inside the furnace is limited due to the size of the furnace and volume of processing gas required. For instance, changing or fine tuning the processing gas mixture in the batch processing furnace may require a considerable amount of time due to the volume of gas required to fill the furnace. Additionally, as the water vapor and oxygen mixture flows across the batch of substrates, the water vapor pressure decreases as water vapor is absorbed by the substrates. Thus, the ratio of oxygen to water vapor increases as it flows from the inlet, across the substrates, and to the exit of the furnace. The decreasing vapor pressure results in decreasing film growth and decreased uniformity in the batch. Throughput of substrate fabrication may also be diminished due to the time that the substrates must stay in queue both prior and subsequent to the furnace processing in addition to the time required for conventional furnace annealing.

Therefore, a need exists for improvements in processes and apparatus for producing high aspect ratio isolation structures and the like free of voids and seams.

### SUMMARY OF THE INVENTION

In one embodiment of the present invention, a method for curing a dielectric material formed in a trench on a substrate comprises transferring the substrate into a processing region of a chamber configured to expose ultraviolet radiation to the substrate, flowing a gas mixture into the processing region of the chamber, and exposing the gas mixture to ultraviolet radiation. In one embodiment, the gas mixture comprises one or more of water vapor, ozone, and hydrogen peroxide. In one embodiment, the gas mixture is exposed to ultraviolet radiation to generate a hydroxyl radical. In one embodiment, the substrate is exposed to ultraviolet radiation.

In another embodiment, a method for forming dielectric material in a trench on a substrate comprises transferring the substrate into a processing region of a first process chamber in a multi-chamber processing system, introducing a first gas mixture at a first flow rate into the processing region of the first process chamber, introducing a second gas mixture at a second flow rate into the processing region of the first process chamber, transferring the substrate from the processing region of the first process chamber into the processing region of a second process chamber in the multi-chamber processing system, flowing a third gas mixture into the processing region of the second process chamber, and exposing the third gas mixture to ultraviolet radiation. In one embodiment, the first process chamber is configured to deposit the dielectric material on the substrate. In one embodiment, the second gas mixture is introduced into the processing region of the first process chamber at a flow rate that is greater than the rate at which the first gas is introduced into -the processing region of the first process chamber. In one embodiment, the second process chamber is configured to expose the substrate to ultraviolet radiation. In one embodiment, the third gas mixture comprises one or more of water vapor, ozone, and hydrogen peroxide. In one embodiment, the third gas mixture is exposed to ultraviolet radiation to generate a hydroxyl radical. In one embodiment, the substrate is exposed to ultraviolet radiation.

In yet another embodiment of the present invention, a multi-chamber processing system comprises a first chamber configured to deposit a dielectric material, a second chamber configured to cure the dielectric material, a transfer robot configured to transfer a substrate from the first chamber to the second chamber, and a system controller. In one embodiment, the system controller is programmed to provide control signals to deposit the dielectric material at first and second rates. In one embodiment, the second rate is higher than the first rate. In one embodiment, the system controller is programmed to introduce a gas mixture comprising one or more of water vapor, ozone, and hydrogen peroxide into the second chamber and expose the gas mixture to ultraviolet radiation.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (prior art) is a simplified cross-sectional view of an exemplary trench filled with a dielectric material deposited using a conventional process.

FIG. 2 (prior art) is a simplified cross-sectional view of another example of a trench filled with a dielectric material deposited using a conventional process.

FIG. 3 (prior art) is a simplified cross-sectional view of the trench in FIG. 2 after planarizing.

FIG. 4 is a schematic depiction of the chemical mechanism for repairing a seam formed in a trench filled with dielectric material.

FIG. 5 is a plan view of an exemplary processing system for use according to one embodiment of the present invention.

FIG. 6 is an isometric view of one embodiment of a tandem process chamber configured for ultraviolet (UV) curing.

FIG. 7 is a partial cross-sectional view of one embodiment of the tandem process chambers in FIG. 6.

FIG. 8 depicts an exemplary method according to one embodiment of the current invention.

FIG. 9 is a plot comparing Fourier transform infrared spectra of a trench fill dielectric film deposited prior to and subsequent to UV steam annealing according to one embodiment of the present invention.

FIG. 10 is a plot comparing a thermally steam annealed trench fill dielectric film to a UV steam annealed trench fill dielectric film.

### DETAILED DESCRIPTION

Embodiments of the present invention include methods and apparatus for curing dielectric material to produce void and seam free isolation structures and the like. One embodiment includes the use of ultraviolet (UV) radiation to anneal and densify dielectric materials used to fill gaps and trenches in substrates.

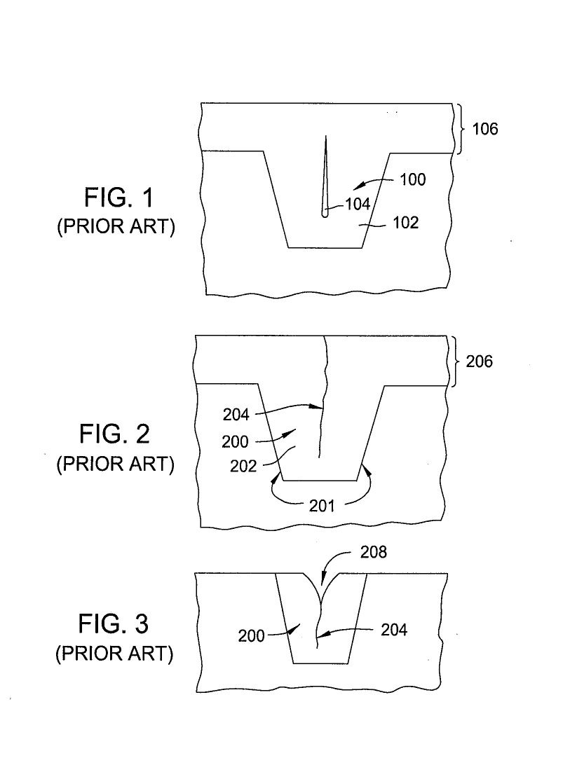

FIG. 1 is a simplified cross-sectional view of an exemplary trench 100 filled with a dielectric material 102, such as silicon oxide, deposited utilizing a conventional process. As shown, the increased rate of deposition of dielectric material 102 on the raised edges of the trench 100 may result in pinching off the trench 100 and creating an undesirable void 104 within the trench 100. A bulk dielectric layer 106 is formed over the dielectric filled trench 100. The bulk dielectric layer 106 provides additional dielectric material to serve as the starting point for continued processing, such as CMP, which may expose the void 104.

FIG. 2 is a simplified cross-sectional view of another example of a trench 200 filled with a dielectric material 202, such as silicon oxide, deposited utilizing a conventional process. A weak seam 204 is formed at the junction of the dielectric material 202 grown from the opposing sidewalls 201 of the trench 200. The weak seam 204 may result in the dielectric material 202 along the seam 204 being removed at faster rates relative to the surrounding dielectric material 202 when a bulk layer 206 is exposed to an etchant in subsequent processing, such as CMP.

FIG. 3 is a simplified cross-sectional view of the trench 200 depicted in FIG. 2 after CMP processing. The enhanced rate of etching along the seam 204 results in unwanted dishing 208 in the surface of the dielectric filled trench 200.

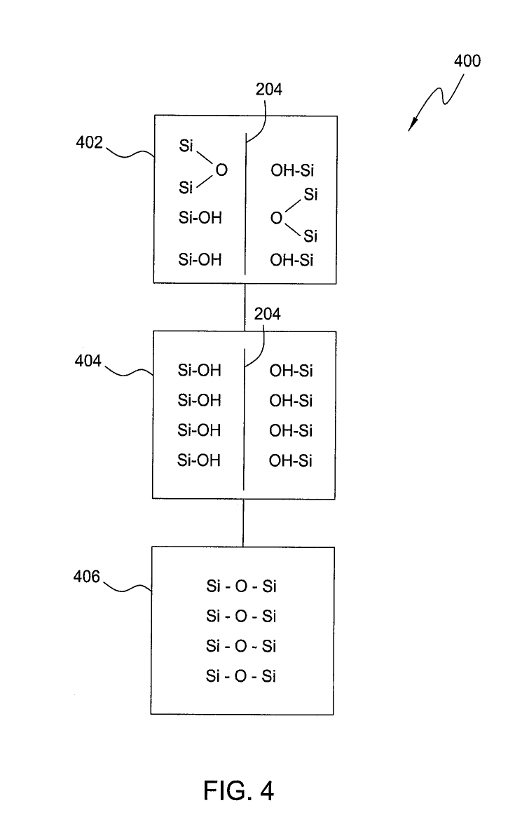

FIG. 4 is a schematic depiction of the mechanism 400 for repairing a seam formed in dielectric trench fill material, such as seam 204. Dielectric material deposition 402 has a low density of silanol (SiOH), resulting in weak adherence at the seam 204. Steam annealing 404 increases silanol density at the seam 204 by incorporating hydroxyl (—OH) groups. High temperature anneal 406 further promotes combining of hydroxyl groups to release moisture and facilitate stable Si—O—Si bonds, resulting in seam free oxide filled trenches.

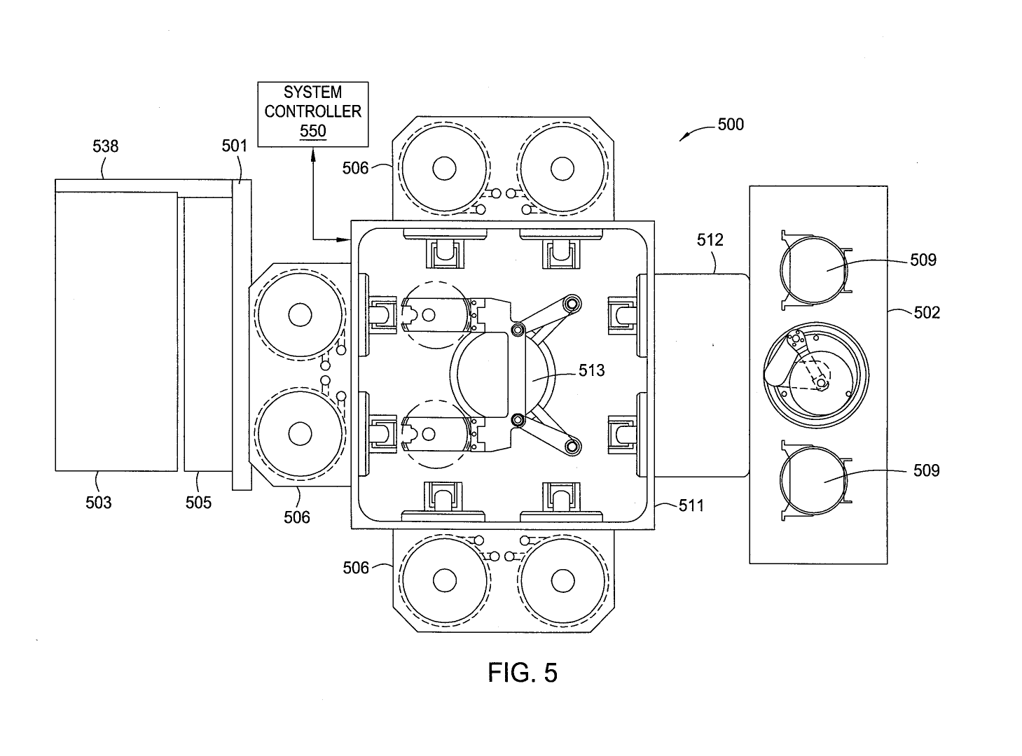

FIG. 5 is a plan view of an exemplary processing system 500 for use according to one embodiment of the present invention. The processing system 500 may be a self-contained system having the necessary processing utilities supported on a mainframe structure 501. The processing system 500 may include a front end staging area 502 where substrate cassettes 509 are supported and substrates are loaded into and unloaded from a loadlock chamber 512. The processing system 500 may further include a transfer chamber 511 housing a substrate handler 513, a series of tandem process chambers 506 mounted on the transfer chamber 511, and a back end 538, which houses the support utilities needed for operation of the system 500. In one embodiment, the back end 538 includes a gas panel 503 and a power distribution panel 505.

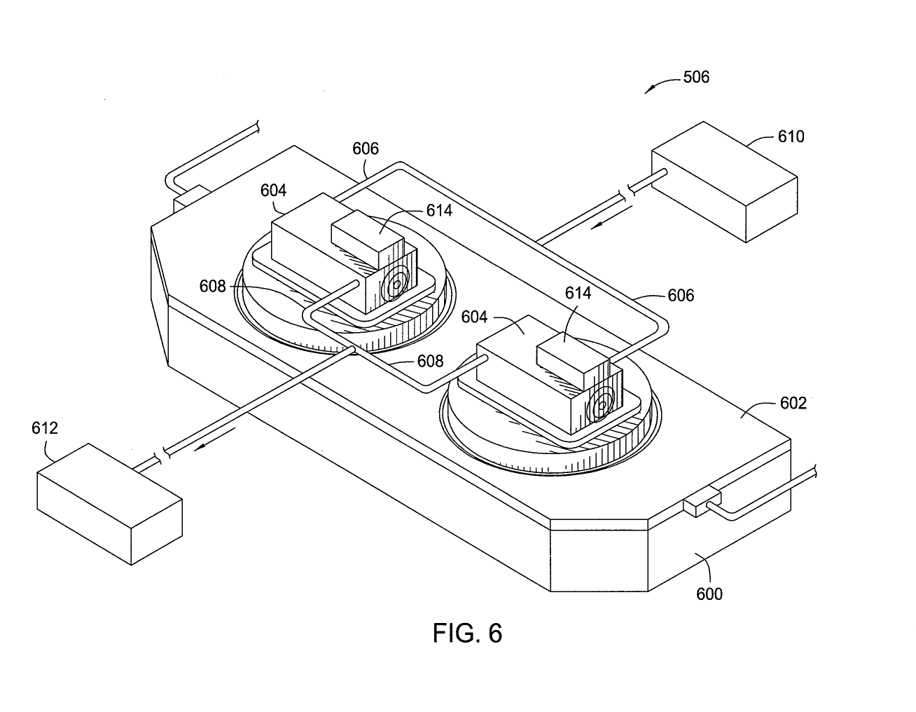

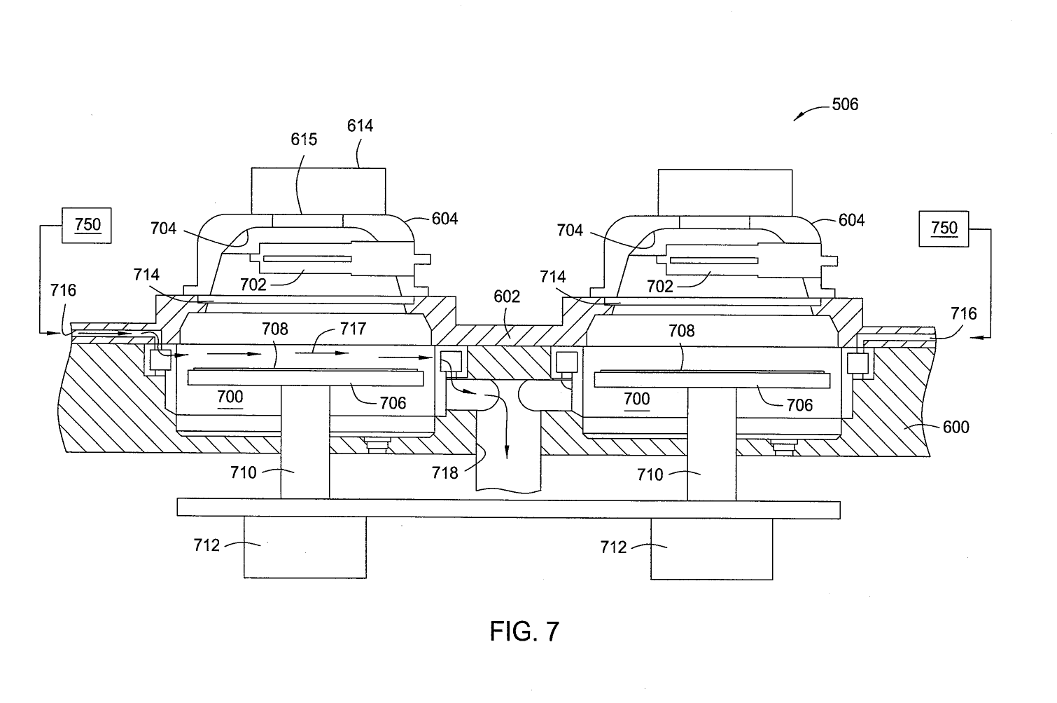

In one embodiment, each of the tandem process chambers 506 includes two processing regions for processing substrates (see FIGS. 6 and 7). The two processing regions may share a common supply of gases, a common pressure control, and a common process gas exhaust/pumping system. Modular design of the system may enable rapid conversion from one configuration to another. The arrangement and combination of chambers may be altered for purposes of performing specific process steps. In one embodiment, at least one of the tandem process chambers 506 may include a lid according to aspects of the invention as described below that includes one or more UV lamps for use in curing a dielectric material. In one embodiment, at least one of the tandem process chambers 506 is a chemical vapor deposition chamber for use in depositing a dielectric material onto a substrate for filling a trench. In one embodiment, two of the tandem process chambers 506 have UV lamps and are configured as UV curing chambers to run in parallel. In one embodiment, all three of the tandem process chambers 506 have UV lamps and are configured as UV curing chambers to run in parallel.

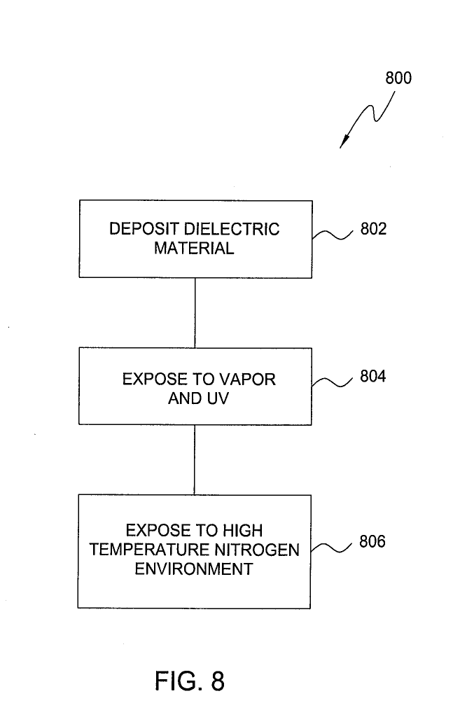

In one embodiment, the processing system 500 is equipped with a system controller 550 programmed to control and carry out various processing methods and sequences, such as the process depicted in FIG. 8 and subsequently described, as well as others performed in the processing system 500. The system controller 550 generally facilitates the control and automation of the overall system and typically may include a central processing unit (CPU) (not shown), memory (not shown), and support circuits (not shown). The CPU may be one of any computer processors used in industrial settings for controlling various system functions and chamber processes.

In one embodiment the system controller 550 provides control signals to deposit dielectric material into a trench formed on a substrate in one or more of the tandem process chambers 506 at a first and second rates, wherein the second rate is higher than the first rate. In one embodiment, the system controller 550 is further programmed provide control signals to introduce a gas mixture comprising one or more of water vapor, ozone, and hydrogen peroxide into the tandem process chamber 506 and expose the gas mixture to UV radiation. In one embodiment, the system controller 550 is further programmed to provide control signals to expose the substrate to UV radiation within the tandem process chamber 506.

FIG. 6 illustrates one embodiment of one of the tandem process chambers 506 of the semiconductor processing system 500 that is configured for UV curing. The tandem process chamber 506 may include a body 600 and a lid 602 that can be hinged to the body 600. Coupled to the lid 602 are two housings 604 that are each coupled to inlets 606 along with outlets 608 for passing cooling air through an interior of the housings 604. A central pressurized air source 610 provides a sufficient flow rate of air to the inlets 606 to insure proper operation of any UV lamp bulbs and/or power sources 614 for the bulbs associated with the tandem process chamber 506. The outlets 608 receive exhaust air from the housings 604, which is collected by a common exhaust system 612.

FIG. 7 depicts a partial sectional view of one embodiment of the tandem process chamber 506 with the lid 602, the housings 604, and the power sources 614. Each of the housings 604 cover a respective one of two UV lamp bulbs 702 disposed respectively above two process regions 700 defined within the body 600. Each of the process regions 700 includes a heating pedestal 706 for supporting a substrate 708 within the process regions 700. The pedestals 706 may comprise ceramic or metal, such as aluminum. In one embodiment, the pedestals 706 couple to stems 710 that extend through a bottom of the body 600 and are operated by drive systems 712 to move the pedestals 706 in the processing regions 700 toward and away from the UV lamp bulbs 702. The drive systems 712 may also rotate and/or translate the pedestals 706 during curing to further enhance uniformity.

In general, embodiments contemplate any UV source, such as mercury microwave arc lamps, pulsed xenon flash lamps, and high-efficiency UV light emitting diode arrays. The UV lamp bulbs 702 may be sealed plasma bulbs filled with one or more gases such as xenon or mercury for excitation by the power sources 614. In one embodiment the power sources 614 are microwave generators that may include one or more magnetrons (not shown) and one or more transformers (not shown) to energize filaments of the magnetrons. In one embodiment having kilowatt microwave power sources, each of the housings 604 includes an aperture 615 adjacent the power sources 614 to receive up to about 6000 W of microwave power form the power sources 614 to subsequently generate up to about 100 W of UV light from each of the UV lamp bulbs 702. In one embodiment, the UV lamp bulbs 702 may include an electrode or filament therein such that the power sources 614 represent circuitry and/or current supplies, such as direct current (DC) or pulsed DC, to the electrode.

In one embodiment, the power sources 614 may include radio frequency (RF) power sources that are capable of excitation of the gases within the UV lamp bulbs 702. The configuration of the RF excitation in the bulb may be capacitive or inductive. An inductively coupled plasma (ICP) bulb may be used to efficiently increase bulb brilliancy by generation of denser plasma than with the capacitively coupled discharge. In addition, the ICP lamp may eliminate degradation in the UV output due to electrode degradation resulting in a longer life bulb for enhance system productivity.

In one embodiment, UV light emitted from the UV lamp bulbs 702 enters the processing regions 700 by passing through windows 714 disposed in apertures in the lid 602. The windows 714 may be made of an OH free synthetic quartz glass and of a thickness sufficient to maintain vacuum without cracking. In one embodiment, the windows 714 are fused silica that transmits UV light down to approximately 150 nm.

In one embodiment, the processing regions 700 provide volumes capable of maintaining pressures from about 1 Torr to about 650 Torr. In one embodiment, processing gases 717 may enter the process regions 700 via one of two inlet passages 716. The processing gases 717 may exit via a common outlet port 718. In one embodiment, the cooling air supplied to the interior of the housings 604 is isolated from the process regions 700 by windows 714.

In one embodiment, the inlet passages 716 are in fluid communication with a vapor delivery system 750. The vapor delivery system may be configured to produce and deliver, among other things, deionized water vapor through the inlet passages 716 and into the processing region 700. In one embodiment, components of the vapor delivery system 750, inlet passages 716, and other components in fluid communication with the processing region 700 may comprise materials having passivated or coated surfaces to prevent corrosive attack from deionized water vapor.

In one embodiment, the components of the vapor delivery system 750, and components in fluid communication therewith, comprise electro-polished stainless steel. During electropolishing of stainless steel, a chemical reaction is produced that selectively removes iron and nickel atoms from the surface of the component, leaving a surface layer consisting essentially of chromium and its oxides. The result is a surface layer substantially resistant to attack from potentially corrosive substances, such as deionized water vapor.

In one embodiment, the components of the vapor delivery system 750, and components in fluid communication therewith, comprise stainless steel having a thin layer of chromoxide film grown on the surface thereof. The resulting surface layer is substantially resistant to attack from potentially corrosive substances, such as deionized water vapor.

In one embodiment, the components of the vapor delivery system 750, and components in fluid communication therewith, comprise stainless steel having a polymer coating, such as TEFLON® PTFE (polytetrafluoroethylene). The coating is extremely temperature resistant, and the result is a surface substantially resistant to the attack of potentially corrosive substances, such as deionized water vapor.

In one embodiment, each of the housings 604 includes an interior parabolic surface defined by a cast quartz lining 704 coated with a dichroic film. The quartz linings 704 reflect UV light emitted from the UV lamp bulbs 702 and are shaped to fit the cure processes based on the pattern of UV light directed by the quartz linings 704 into the process regions 700. In one embodiment, the quartz linings 704 adjust to better suit each process or task by moving and changing the shape of the interior parabolic surface. Additionally, the quartz linings 704 may transit infrared light and reflect UV light emitted by the UV lamp bulbs 702 due to the dichroic film.

In one embodiment, rotating or otherwise periodically moving the quartz linings 704 during curing may enhance the uniformity of illumination in the substrate plane. In one embodiment, the entire housings 604 may rotate or translate periodically over the substrates 708 while the quartz linings 704 are stationary with respect to the bulbs 702. In one embodiment, rotation or periodic translation of the substrates 708 via the pedestals 706 may provide relative motion between the substrates 708 and the bulbs 702 to enhance illumination and curing uniformity.

In one embodiment, the UV lamp bulbs 702 may be an array of UV lamps. In one embodiment, the array of UV lamps may include at least one bulb for emitting a first wavelength distribution and at least one bulb for emitting a second wavelength distribution. The curing process may thus be controlled by defining various sequences of illumination with the various lamps within a given curing chamber in addition to adjustments in gas flows, composition, pressure, and substrate temperature.

FIG. 8 depicts an exemplary method 800 according to one embodiment of the current invention. At block 802, a dielectric layer is deposited on a substrate. The oxide layer may be deposited using HARP techniques for varying the deposition rate of the dielectric materials during the formation of the dielectric layer. An exemplary deposition process follows.

The substrate is first placed in a process chamber, such as tandem process chamber 506. In one embodiment, the tandem process chamber 506 is a chemical vapor deposition (CVD) chamber. In one embodiment, a precursor material may flow through a manifold in fluid connection with the process chamber 506. This may include flowing an oxidizing gas precursor, a silicon-containing precursor, and a hydroxyl-containing precursor through the manifold. Each precursor flows through the manifold and into the process chamber 506 at an initial flow rate.

Depending on the type of process used, the precursor materials may help form plasma whose products are used to form the dielectric layer on the substrate. The deposition process may comprise techniques such as plasma enhanced chemical vapor deposition (PECVD), high density plasma chemical vapor deposition (HDPCVD), atmospheric pressure chemical vapor deposition (APCVD), sub-atmospheric chemical vapor deposition (SACVD), or low-pressure chemical vapor deposition (LPCVD).

The initial flow rates of the precursors establish first flow rate ratios for the silicon-containing precursor to oxidizing gas precursor and the silicon-containing precursor to hydroxyl-containing precursor. For the initial deposition of dielectric material in high aspect ratio trenches, the ratio of silicon-containing precursor to oxidizing gas precursor may be relatively low to provide a slower deposition of dielectric material in the trench. As the deposition progresses, the ratio of silicon-containing precursor to oxidizing gas precursor may be increased to increase the deposition rate of the dielectric material. The adjustment may be made at a stage of the deposition when there is reduced risk of the higher deposition rate causing voids in the trench.

Once the oxide layer is deposited in block 802, the dielectric layer may be annealed to increase the silanol density in the dielectric layer at the seam in the high aspect ratio trench in block 804. In one embodiment, the annealing process is accomplished through exposure to a vapor and UV radiation.

The substrate may be removed from the process chamber 506 used in block 802 to deposit the dielectric layer on the substrate and placed into a UV exposure chamber, such as another tandem processing chamber 506. The vapor delivery system 750 in fluid communication with the inlet passages 716 of the process chamber 506 introduces vapor to the surface of the substrate. The surface of the substrate may simultaneously be exposed to UV radiation within the process chamber 506 from UV lamp bulbs 702. The UV radiation may breakdown the vapor delivered to the substrate such that hydroxyl groups are incorporated into the dielectric material, increasing the density of silanol, particularly at the seam.

In one embodiment, the vapor delivery system 750 delivers water vapor (H₂O) to the surface of the substrate for dissociation of hydroxyl groups. In one embodiment, Ozone (O₃) may be introduced as well to react with the water vapor in the presence of the UV radiation. In one embodiment, hydrogen peroxide (H₂O₂) may be delivered to the surface of the substrate for dissociation of hydroxyl groups in the presence of the UV radiation. In one embodiment, the vapor delivery system may deliver water vapor, ozone, and hydrogen peroxide to react and dissociate to form hydroxyl groups in the presence of the UV radiation. Thus, the hydroxyl groups may be generated according to the following chemical equations:

H₂0+(UV)→OH+H

O₃+(UV)→O₂+O

H₂O+O→2 OH

H₂O₂+(UV)→H2O+O

H₂O+O→2 OH

The substrate is further exposed to the UV radiation for further curing. Consequently, the hydroxyl groups combine to release moisture from the dielectric layer. The further UV curing also facilitates stable, network Si—O—Si bonds.

At block 806, nitrogen (N2) may be introduced into the process region 700 for further annealing and densification of the dielectric material layer. In one embodiment, the nitrogen annealing takes place in the same process chamber 506 in which the dielectric material was steam annealed. In one embodiment, the nitrogen annealing takes place in a different process chamber 506 within the processing system 500.

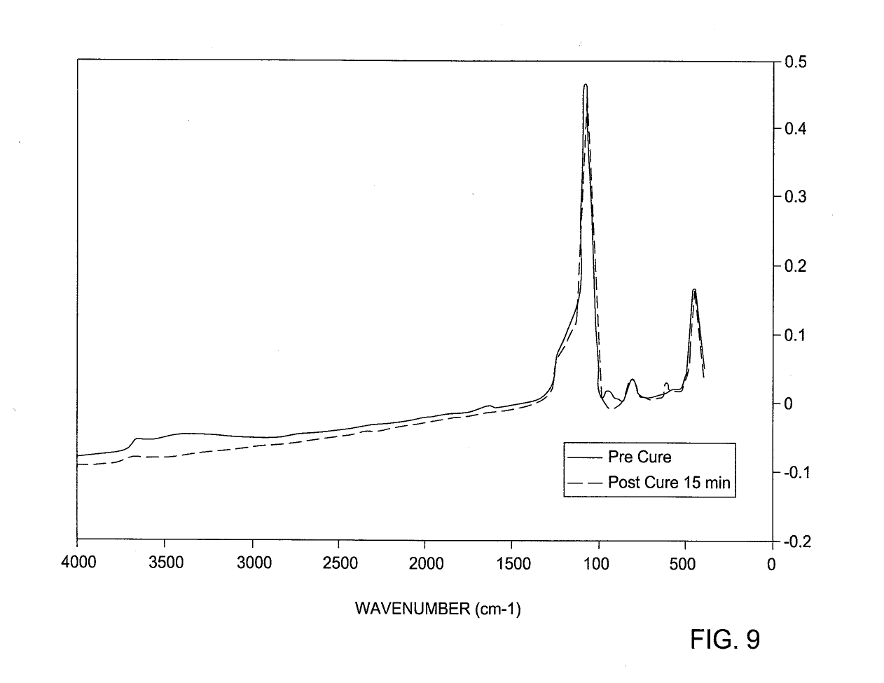

FIG. 9 is a plot comparing Fourier transform infrared (FT-IR) spectra of a trench fill dielectric film deposited prior to and subsequent to UV steam annealing according to one embodiment of the present invention. As shown, the peak height for (—OH) and H2O bonds (at approximately 3500 cm-1) is reduced after UV steam annealing. The reduction in absorption indicates that the UV steam annealing process resulted in moisture desorption of the film.

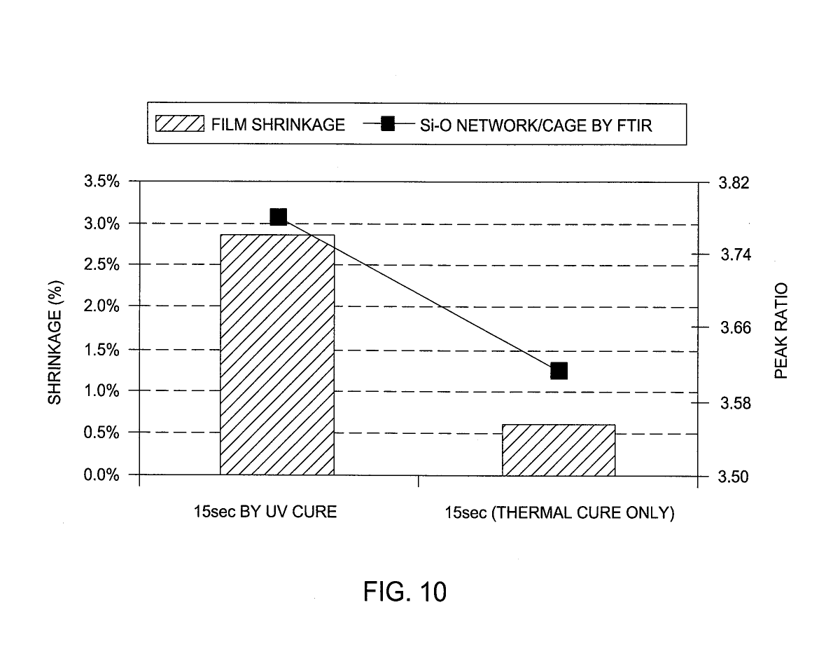

FIG. 10 is a plot comparing a thermally steam annealed trench fill dielectric film to a UV steam annealed trench filling dielectric film. As indicated by the bar graphs, the UV steam annealed film has significantly higher film shrinkage. Additionally, as indicated by the line graph, the UV steam annealed film also has a significantly higher Si—O network to cage ratio. This indicates that the film has very few of undesirable cage bonds and a relatively high number of desirable network bonds. The cage bonds have dangling bonds and are susceptible to attraction hydrogen atoms in the presence of moisture. However, once the film is UV annealed, many of the Si—O cage bonds are converted to network bonds resulting in a more stable, highly moisture resistant film.

Embodiments of the present invention provide increased control of the process of repairing voids and seams in isolation structures and the like by enabling a quick and efficient annealing process in a single substrate process volume. Since the processing region of the UV exposure chambers used in embodiments of the present invention have significantly lower volume than those of batch processing furnaces, greater flexibility in changing or fine tuning the gas mixtures used in the annealing process may be achieved. Moreover, the smaller amount of gas volume needed in the chamber leads to significantly less time required to alter the gas mixtures as desired.

Additionally, the smaller processing volume of embodiments of the present invention leads to increased uniformity in annealing the substrate. Uniformity is a function of temperature and gas pressure in the annealing process. The large volume required for batch furnace annealing leads to non-uniformity of gas pressure across the batch of substrates. In contrast, the process volume required for embodiments of the present invention enables a significantly more constant gas pressure across the substrate, leading to a significant increase in uniformity.

Throughput of the repair process in embodiments of the present invention may be significantly improved in comparison to batch furnace annealing as well. UV annealing requires significantly less time than thermal steam annealing. Additionally, in contrast to batch furnace annealing, embodiments of the present invention require no time in queue prior or subsequent to the anneal process.

Therefore, embodiments of the present invention lead to the production of void and seam free isolation structures and the like, while improving control, uniformity, and throughput over prior art methods and processes.

While the foregoing is directed to embodiments of the present invention, other and further embodiments of the invention may be devised without departing from the basic scope thereof, and the scope thereof is determined by the claims that follow.

1. A method for curing a dielectric material formed in a trench on a substrate, comprising:
transferring the substrate into a processing region of a chamber configured to expose ultraviolet radiation to the substrate;
flowing a gas mixture into the processing region of the chamber, wherein the gas mixture comprises one or more of water vapor, ozone, and hydrogen peroxide;
exposing the gas mixture to ultraviolet radiation to generate a hydroxyl radical; and
exposing the substrate to ultraviolet radiation.

2. The method of claim 1, further comprising thermally annealing the substrate in a nitrogen environment.

3. The method of claim 2, wherein the nitrogen environment is provided in the processing region of the chamber.

4. The method of claim 1, further comprising:
transferring the substrate into a second chamber; and
thermally annealing the substrate in a nitrogen environment.

5. The method of claim 1, wherein the gas mixture comprises water vapor.

6. The method of claim 5, wherein the gas mixture further comprises ozone.

7. The method of claim 5, wherein the gas mixture further comprises hydrogen peroxide.

8. A method for forming dielectric material in a trench on a substrate, comprising:
transferring the substrate into a processing region of a first process chamber in a multi-chamber processing system, wherein the first process chamber is configured to deposit the dielectric material on the substrate;
introducing a first gas mixture at a first flow rate into the processing region of the first process chamber;
introducing a second gas mixture at a second flow rate into the processing region of the first process chamber, wherein the second flow rate is greater than the first flow rate;
transferring the substrate from the processing region of the first process chamber into the processing region of a second process chamber in the multi-chamber processing system, wherein the second process chamber is configured to expose the substrate to ultraviolet radiation;
flowing a third gas mixture into the processing region of the second process chamber, wherein the third gas mixture comprises one or more of water vapor, ozone, and hydrogen peroxide;
exposing the third gas mixture to ultraviolet radiation to generate a hydroxyl radical; and
exposing the substrate to ultraviolet radiation.

9. The method of claim 8, wherein the first and second gas mixtures each comprise an oxidizing gas precursor, a silicon-containing precursor, and a hydroxyl-containing precursor.

10. The method of claim 9, wherein the second gas mixture has a higher ratio of silicon-containing precursor to oxidizing gas precursor than the first gas mixture.

11. The method of claim 8, further comprising:
introducing nitrogen gas into the processing region of the second process chamber; and
thermally annealing the substrate in a nitrogen atmosphere.

12. The method of claim 8, further comprising:
transferring the substrate from the second process chamber to a third process chamber in the multi-chamber processing system; and
thermally annealing the substrate in a nitrogen environment.

13. The method of claim 8, wherein the third gas mixture comprises water vapor.

14. The method of claim 13, wherein the third gas mixture further comprises ozone.

15. The method of claim 13, wherein the third gas mixture further comprises hydrogen peroxide.

16. A multi-chamber processing system, comprising:
a first chamber configured to deposit a dielectric material;
a second chamber configured to cure the dielectric material;
a transfer robot configured to transfer a substrate from the first chamber to the second chamber;
a vapor delivery system in fluid communication with the second chamber; and
a system controller programmed to provide control signals to:
deposit the dielectric material into a trench formed on the substrate at a first and second rates, wherein the second rate is higher than the first rate;
introduce a gas mixture via the vapor delivery system comprising one or more of water vapor, ozone, and hydrogen peroxide into the second chamber; and
expose the gas mixture to ultraviolet radiation.

17. The multi-chamber processing system of claim 16, wherein the vapor delivery system and the second chamber comprise components with passivated surface layers.

18. The multi-chamber processing system of claim 16, wherein the system controller is further programmed to provide control signals to expose the substrate to ultraviolet radiation.

19. The multi-chamber processing system of claim 18, wherein the second chamber is further configured to thermally anneal the substrate in a nitrogen environment.

20. The multi-chamber processing system of claim 18, further comprising a third process chamber configured to thermally anneal the substrate in a nitrogen environment, wherein the transfer robot is further configured to transfer the substrate from the second chamber to the third chamber.
